(19) United States
(12) Patent Application Publication
(10) Pub. No.: US 2025/0132272 A1
(43) Pub. Date: Apr. 24, 2025

(54) ELECTRONIC DEVICE

(71) Applicant: InnoLux Corporation, Miao-Li County (TW)

(72) Inventors: Jui-Jen YUEH, Miao-Li County (TW); Wei-Yuan CHENG, Miao-Li County (TW); Ker-Yih KAO, Miao-Li County (TW)

(21) Appl. No.: 18/888,462

(22) Filed: Sep. 18, 2024

(30) Foreign Application Priority Data
Oct. 19, 2023 (TW) 112139934

(51) Int. Cl. H01L 23/66; H01L 23/00; H01L 23/31; H01L 23/367; H01L 23/498

(52) U.S. Cl. CPC H01L 23/66; H01L 23/3107; H01L 23/49816; H01L 23/49833; H01L 23/49838; H01L 24/08; H01L 23/367; H01L 24/16; H01L 2223/6616; H01L 2223/6677; H01L 2224/08235; H01L 2224/08238; H01L 2224/16227; H01L 2924/15153

(57) ABSTRACT

An electronic device is provided. The electronic device includes a protective layer, a chip disposed on the protective layer, a first connector electrically connected to the chip, and an antenna unit disposed on the first connector and electrically connected to the chip. The antenna unit includes a pattern layer and a covering layer disposed on the pattern layer. The pattern layer includes a first surface and the covering layer includes a second surface. The first surface is rougher than the second surface.

### CROSS REFERENCE TO RELATED APPLICATIONS

This application claims priority of Taiwan Patent Application No. 112139934 filed on Oct. 19, 2023, the entirety of which is incorporated by reference herein.

### BACKGROUND OF THE INVENTION

### Field of the Invention

The present disclosure relates to an electronic device, and in particular to an integrated wiring structure with an antenna unit.

### Description of the Related Art

Electronic devices have become indispensable products in modern life. However, with the trend of scaling down the size of said electronic devices, current display devices still do not meet expectations in all respects. For example, in the existing automotive millimeter-wave radar, the antenna unit and the signal processing chip are configured in different areas on the same circuit board. This separate configuration causes the size of the device to be larger, and the cost is also higher. Therefore, developing a design for scaling down electronic devices is one of the current research topics in the industry.

### BRIEF SUMMARY OF THE INVENTION

The present disclosure provides an electronic device. The electronic device includes a protective layer, a chip disposed on the protective layer, a first connector electrically connected to the chip, and an antenna unit disposed on the first connector and electrically connected to the chip. The antenna unit includes a pattern layer and a covering layer disposed on the pattern layer. The pattern layer includes a first surface and the covering layer includes a second surface. The roughness of the first surface is greater than the roughness of the second surface

A detailed description is given in the following embodiments with reference to the accompanying drawings.

### BRIEF DESCRIPTION OF THE DRAWINGS

FIG. 1 shows a schematic cross-sectional view of an electronic device according to some embodiments of the present disclosure.

FIGS. 2A-2C show schematic cross-sectional views of different configurations of the antenna unit of electronic devices according to some embodiments of the present disclosure.

FIGS. 3A-3F show cross-sectional schematic diagrams of methods of forming electronic devices according to some embodiments of the present disclosure.

FIG. 4 shows a schematic cross-sectional view of an electronic device according to other embodiments of the present disclosure.

FIG. 5 shows a schematic cross-sectional view of an electronic device according to still other embodiments of the present disclosure.

FIG. 6A-6E illustrate schematic cross-sectional views of methods of forming electronic devices according to still other embodiments of the present disclosure.

### DETAILED DESCRIPTION OF THE INVENTION

The electronic device of the embodiments of the present disclosure will be described in detail in the following context. It should be noted that many different embodiments provided in the following description are used to implement different aspects of the embodiments. The specific elements and configurations described in the following detailed description are set forth in order to clearly describe some embodiments of the present disclosure. It will be apparent that the exemplary embodiments set forth herein are used merely for the purpose of illustration, and are not used to limit the scope of the present disclosure. In addition, the drawings of different embodiments may use like and/or corresponding numerals to denote like and/or corresponding elements in order to clearly describe the present disclosure. However, the use of like and/or corresponding numerals in the drawings of different embodiments is only for the purpose of simply and clearly describing some embodiments of the present disclosure, but does not suggest any correlation between different embodiments.

The present disclosure may be understood by referring to the following detailed description in conjunction with the accompanying drawings. It should be noted that in order to facilitate the reader's understanding and the simplicity of the figures, the multiple drawings in this disclosure only depict a part of the electronic device, and the specific elements in the figures are not drawn according to actual scale. In addition, the number and size of each element in the figure are only for illustration, and are not used to limit the scope of the disclosure. In addition, the number and the size of each element in the figures are only for illustration, and are not used to limit the scope of the disclosure.

It should be appreciated that the elements or devices in the figures of the present disclosure may be present in any form or configuration known to those with ordinary skill in the art. In addition, in the embodiments, relative expressions are used. For example, “lower”, “bottom”, “higher” or “top” are used to describe the position of one element relative to another. It should be appreciated that if a device is flipped upside down, an element that is “lower” will become an element that is “higher”. The descriptions of the exemplary embodiments are intended to be read in connection with the accompanying drawings, which are to be considered part of the entire written description. In addition, the following expression “the first element is disposed on the second element” includes the conditions where the first element and the second element are in direct contact, or one or more other elements are disposed between the first element and the second element so that they are not in direct contact.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, areas, steps, operations and/or components would be pointed to existence, but not limited to the existence of one or more corresponding features, areas, steps, operations and/or components.

In addition, the relative expressions mentioned in the context, such as “upper”, “lower”, “bottom”, “front”, “back”, “left” or “right”, are used to describe the direction referring to figures. Therefore, the directional terms used are for illustration, and are not used to limit the scope of the disclosure. Each of the figures presents the general features of the methods, structures, and/or materials used in specific embodiments. However, these figures should not be construed as defining or limiting the scope or characteristics covered by these embodiments. For example, for the sake of clarity, the relative size, thickness, and position of each layer, region, and/or structure may be shrink or enlarged.

When a corresponding component (such as a film layer or a region) is referred to as “on another component”, it can be directly disposed on another component, or other components are disposed between the two. On the other hand, when a component is referred to as “directly on another component”, no component is disposed between the two. In addition, when a component is referred to as “on another member”, the two have a vertical relationship in the top view direction. Thus, the component may be on or under the other one, and the up-down relationship depend on the orientation of the device.

In addition, it should be understood that, although the terms “first”, “second”, “third” or the like may be used herein to describe various elements, components, or portions, these elements, components, or portions should not be limited by these terms. These terms are only used to distinguish one element, component, region, layer or portion from another element, component, region, layer or portion. Thus, a first element, component, region, layer or portion discussed below could be termed a second element, component, region, layer or portion without departing from the teachings of the present disclosure.

The terms “about”, “substantially”, “equal”, or “same” generally mean within 10% of a given value or range, or mean within 5%, 3%, 2%, 1%, or 0.5% of a given value or range. The given value here is an approximate value. That is, “about”, “substantially” may be still implied without a specific description of “about”, “substantially”. In addition, the phrase “in a range from a first value to a second value” indicates the range includes the first value, the second value, and other values in between.

It should be appreciated that, in the embodiments described in the following, the several features in different embodiments may be replaced, reorganized, and mixed to complete other embodiments without departing from the spirit of the present disclosure. The features of the various embodiments can be used in any combination as long as they do not depart from the spirit and scope of the present disclosure.

In the present disclosure, the thickness, length, and width can be measured by using an optical microscope, and the thickness can be measured by the cross-sectional image in the electron microscope, but it is not limited thereto. In addition, a certain error may be present in a comparison with any two values or directions. If the first value is equal to the second value, it implies that an error of about 10% between the first value and the second value may be present. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

Embodiments of the present invention integrate the antenna unit and the signal processing chip in the vertical direction to integrate device, thereby achieving the effect of reducing size and cost. In addition, in embodiments of the present invention, the pattern layer may be protected by disposing the covering layer on the pattern layer in the antenna unit. Furthermore, since the surface roughness between the covering layer and the pattern layer is greater than the roughness of the surface of the covering layer that contacts the air, it can resist oxidation and reduce signal loss while ensuring the adhesion of the pattern layer.

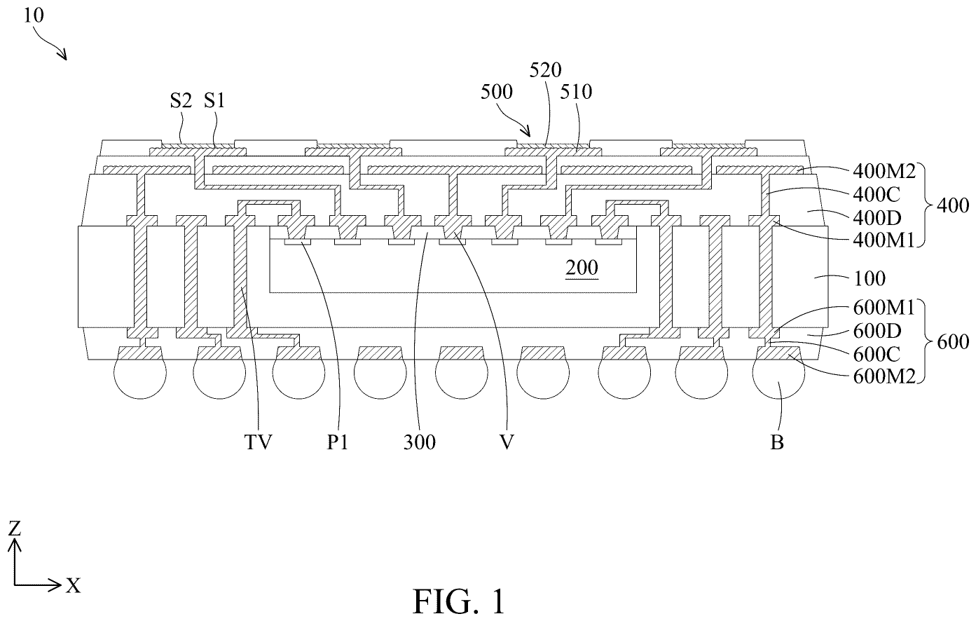

First, please refer to FIG. 1, FIG. 1 shows a schematic cross-sectional view of an electronic device 10 according to some embodiments of the present disclosure.

In some embodiments, the electronic device 10 may include a power module, a semiconductor packaging device, a display device, a backlight device, an antenna device, a sensing device or a splicing device, but is not limited thereto. The electronic device may be a bendable electronic device or a flexible electronic device. The electronic device may include passive components and active components, such as capacitors, resistors, inductors, diodes, transistors, and the like. The diode may include a light emitting diode or a photodiode, but is not limited thereto.

The display device may be a non-self-luminous display device or a self-luminous display device. The self-luminous display device may include light emitting diodes, such as organic light emitting diodes (OLED), sub-millimeter light emitting diodes (mini LED), micro light emitting diodes (micro LED) or quantum dots light emitting diodes (quantum dot LEDs, such as QLED, QDLED), fluorescence, or phosphorus, but are not limited thereto. The non-self-luminous display device may be an electrowetting display device, an electrophoretic or a liquid crystal display device, but is not limited thereto. The liquid crystal display device may be a twisted nematic (TN) liquid crystal display device, a super twisted nematic (STN) liquid crystal display device, or a double layer super twisted nematic (DSTN) liquid crystal display device, vertical alignment (VA) liquid crystal display device, horizontal electric field effect (In-Plane Switching, IPS) liquid crystal display device, cholesterol liquid crystal display device, blue phase LCD device, marginal field effect (FFS) LCD device, low temperature polysilicon LCD device (LTPS) or any other suitable LCD device.

The antenna device may be a liquid crystal type antenna device or a non-liquid crystal type antenna device, and the sensing device may be a sensing device that senses capacitance, light, heat energy or ultrasonic waves, but is not limited thereto. The splicing device may be, for example, a display splicing device or an antenna splicing device, but is not limited thereto.

In some embodiments, the electronic device 10 may be, for example, a semiconductor packaging component, including a ball grid array (BGA), a chip scale package (CSP), a 2.5D/3D package, a Chip on Wafer on Substrate (CoWoS), (including Chip-on-Wafer (CoW) and Wafer-on-Substrate (WoS)), but is not limited to this. In the following, semiconductor packaging components will be used as electronic devices to illustrate the contents of the embodiments of the present invention, but the embodiments of the present invention are not limited thereto.

First, as shown in FIG. 1, the electronic device 10 includes a protective layer 100. In some embodiments, the protective layer 100 is used to protect the chip 200 from being affected by subsequent process. That is, the protective layer 100 may be an encapsulation layer of the chip. In some embodiments, the protective layer 100 may be a single-layer or multi-layer structure. In some embodiments, the thickness of the protective layer 100 may be, for example, 100 um-700 um, but is not limited thereto. In some embodiments, the protective layer 100 may include solid molding materials (such as epoxy molding compound (EMC)), other organic materials, and inorganic materials. For example, it may include organic resins, epoxy resins, epoxy molding compound (EMC), ceramics, poly (methyl methacrylate) (PMMA), polydimethylsiloxane (PDMS), glass, and other suitable materials or combinations of the above materials, but is not limited thereto. The protective layer 100 may include fillers, such as silicon oxide, but is not limited thereto. According to some embodiments, the particle size of the filler is greater than or equal to 0.05 micrometer (mm) and less than or equal to 30 micrometer (mm), or greater than or equal to 0.1 micrometer (mm) and less than or equal to 25 micrometer (mm). For example, the protective layer 100 may include a stack of more than one of epoxy resin, phenolic resin, free radical initiator, catalyst, silicon dioxide powder, and the like.

In some embodiments, the protective layer 100 may include at least one via hole TV penetrating from one surface of the protective layer 100 to another surface to electrically connect the first connector 400 and the second connector 600 described subsequently later.

Next, as shown in FIG. 1, the electronic device 10 includes a chip 200. In one embodiment, the chip 200 may be disposed on the protective layer 100. In another embodiment, the chip 200 is surrounded by the protective layer 100. In some embodiments, the bottom surface and side surfaces of the chip 200 may be completely covered by the protective layer 100.

In some embodiments, the chip 200 may be, for example, made of a silicon wafer, III-V group compounds (such as gallium arsenide (GaAs), gallium nitride (GaN), and silicon carbide (SiC)), sapphire, or glass. Made of wafers, but is not limited thereto. The chip 200 may be a known good die (KGD), which may include, for example, an integrated circuit (IC), a transistor, a silicon controlled rectifier (SCR), a valve, or a thin film transistor, a capacitor, an inductor, a variable capacitance, a filter, a resistor, a diode, a light-emitting diode, a microelectromechanical system (MEMS), a liquid crystal chip, a connector, an interposer, a redistribution layer (RDL) and other components, but is not limited thereto. In the embodiment of the present invention, the chip 200 is illustrated using an integrated circuit (IC) as an example.

Next, as shown in FIG. 1, the electronic device 10 includes a plurality of pads Pl and a plurality of vias V electrically connecting the chip 200 and the first connector 400 subsequently described. The pads Pl and the vias V may include the same or different conductive materials, such as metal or metal alloy, but are not limited thereto. For example, it may be nickel (Ni), copper (Cu), gold (Au), tin (Sn), aluminum (Al), or the like.

It should be noted that in the context, “electrical connection” may include direct or indirect electrical connection by actual wiring, or coupling that transmits signals through direct physical contact or non-physical contact.

Next, as shown in FIG. 1, the electronic device 10 includes a dielectric layer 300 disposed on the chip 200 to protect the chip from subsequent processes (such as the process of forming the first connector 400 and the antenna unit 500 and the like) and avoid damage to it.

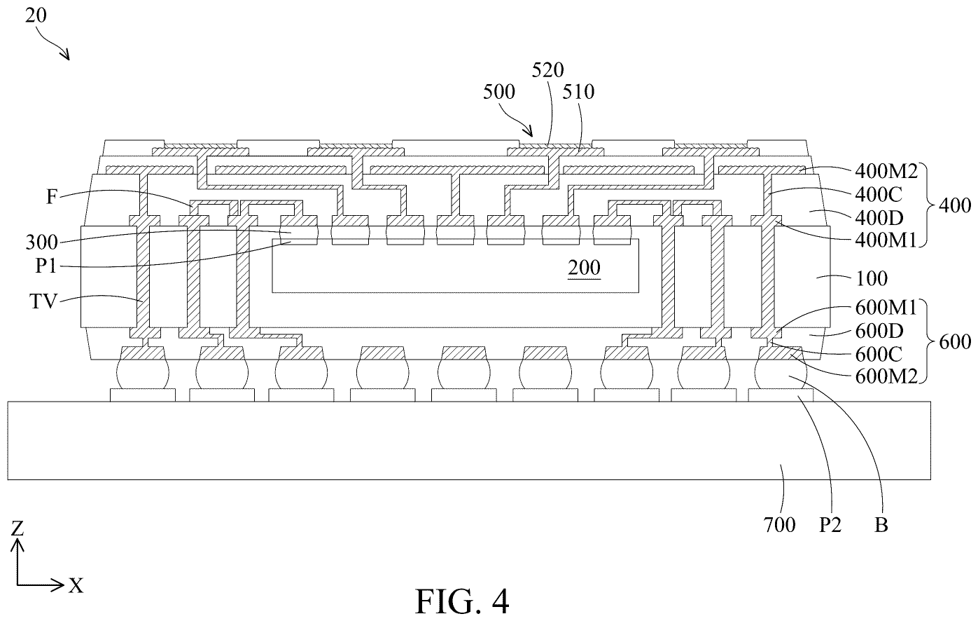

In some embodiments, the dielectric layer 300 may completely cover the top surface of the chip 200. For example, in the embodiment of FIG. 1, the top surface of the chip 200 is covered by the dielectric layer 300 described subsequently. In other embodiments, the dielectric layer 300 may be divided into a plurality of dielectric blocks and only cover part of the top surface of the chip 200 (referring to FIG. 4).

In some embodiments, dielectric layer 300 may include dielectric materials. For example, polyethylene terephthalate (PET), polyimide, photosensitive polyimide (PSPI), liquid crystal polymer (LCP), cyclo olefin polymer (COP), epoxy resin, Ajinomoto Build-up Film (ABF), bismaleimide, fluororesin and/or other suitable materials or combinations of the above, but not limited thereto. In the embodiment of the present invention, the dielectric layer 300 has a different dielectric material than the protective layer 100. For example, the dielectric layer 300 includes Ajinomoto build-up film (ABF) and the protective layer 100 includes epoxy molding compound (EMC).

Next, as shown in FIG. 1, the electronic device 10 includes a first connector 400 that is electrically connected to the chip 200. In some embodiments, the first connector 400 may realize the electrical connection relationship required by each component. For example, it may be a redistribution layer (RDL) structure and include a plurality of dielectric layers and a plurality of conductive layers. For example, the redistribution layer structure is electrically connected to each chip 200 through bonding pads. The redistribution layer structure may include at least one conductive layer and at least one dielectric layer, or may redistribute circuits and/or further increase circuit fan-out area, or different electronic devices may be electrically connected to each other through the redistribution layer structure. For example, in the embodiment of the present invention, the first connector 400 is a redistribution layer structure and is electrically connected to the chip 200 through the vias V and the pads P1.

In one embodiment, the chip 200 may be electrically connected to at least one external component through the first connector 400 and the second connector 600, where the external component may include another chip, a resistor, a capacitor, an inductor, and an antenna unit, a sensing unit, a printed circuit board, a driving unit, a combination of the above or other suitable external components or electronic units.

In one embodiment, during the process of forming the electronic device, the warpage of the structure may also be suppressed first through a warpage reduction device, and then through thin film deposition, acid etching, alkali etching, surface treatment, plasma treatment, exposure and/or laser and other processes to form a redistribution layer structure, but it is not limited thereto.

In some embodiments, the first connector 400 may include a conductive layer 400M1, a connecting line segment 400C, a conductive layer 400M2, and a dielectric layer 400D. The conductive layer 400M1 and the conductive layer 400M2 may extend along the first direction X, and the connecting line segment 400C may extend along the second direction Z and electrically connect the conductive layer 400M1 and the conductive layer 400M2. The conductive layer 400M1 may be disposed on the via V and/or on the protective layer 100. The conductive layer 400M2 may be electrically connected to the ground terminal, which is called as a grounding line. The conductive layer 400M2 overlaps the chip 200 in the second direction Z. For example, when the conductive layer 400M2 and the chip 200 are projected onto the protective layer 100 along the second direction Z, the area of the conductive layer 400M2 may cover more than ⅔ of the area of the chip 200. Thereby, the signal of the antenna unit 400 may be shielded from interfering with the chip 200. The conductive layer may include copper, aluminum, titanium, tantalum, or other suitable conductive materials and may be a single layer or a multi-layer stack. The dielectric layer may include organic materials, inorganic materials, dielectric materials or other suitable insulating materials, such as (but not limited to) including polyimide, epoxy resin and/or silicon dioxide, and may be a single layer or multi-layer stacking. In one embodiment, the thickness of the dielectric layer ranges from 0.1 micrometer (μm) to 40 micrometer (μm).

It should be noted that, for the sake of simplicity, only the conductive layer 400M1 and the conductive layer 400M2 are marked in the drawings for explanation. Those with ordinary knowledge in the technical field of the present invention may arrange any other number of conductive layers under the conductive layer 400M1, between the conductive layer 400M1 and the conductive layer 400M2, or on the conductive layer 400M2 according to actual needs.

The conductive layer 400M1, the connecting line segment 400C, and the conductive layer 400M2 may include the same or different conductive materials, such as one or more metals, metal nitrides, conductive metal oxides, suitable materials, or combinations thereof. The metal may include molybdenum, tungsten, titanium, tantalum, platinum or hafnium, but is not limited thereto. The metal nitride may include molybdenum nitride, tungsten nitride, titanium nitride, and tantalum nitride, but is not limited thereto. The conductive metal oxide may include ruthenium oxide and indium tin oxide, but is not limited thereto.

The dielectric layer 400D may include organic or inorganic dielectric materials, such as polyimide, epoxy resin, silicon oxide, silicon nitride, silicon oxynitride, photosensitive resin, dielectric materials, or any other suitable dielectric materials, or combinations of the above, but are not limited thereto. The photosensitive resin may include photosensitive polyimide (PSPI). Materials of the dielectric material may include metal oxides, metal nitrides, metal silicides, transition metal oxides, transition metal nitrides, transition metal silicides, metal oxynitrides, metal aluminates, zirconosilicate, zirconaluminate, and the like, but not limited thereto. For example, high-k dielectric materials may be LaO, AlO, ZrO, TiO, Ta₂O₅, Y₂O₃, SrTiO₃ (STO), BaTiO₃ (BTO), BaZrO, HfO₂, HfO₃, HfZrO, HfLaO, HfSiO, HfSiON, LaSiO, AlSiO, HfTaO, HfTiO, HfTaTiO, HfAlON, (Ba, Sr) TiO₃ (BST), Al₂O₃, other suitable materials, or other dielectric materials with suitable dielectric constants, or combinations of the above, but are not limited thereto. In embodiments of the present invention, the dielectric layer 400D may include a different dielectric material than the dielectric layer 300 and/or the protective layer 100. For example, the dielectric layer 400D may include photosensitive polyimide (PSPI).

Next, as shown in FIG. 1, the electronic device 10 includes an antenna unit 500 disposed on the first connector 400 and electrically connected to the chip 200. In some embodiments, the antenna unit 500 is used to receive and/or transmit antenna signals. In some embodiments, the antenna unit 500 may have a transmitting part and a receiving part that are separate from each other. For example, the antenna unit 500 may be the transmitting end and/or receiving end of the antenna.

In some embodiments, the antenna unit 500 includes a pattern layer 510 and a covering layer 520 disposed thereon. The pattern layer 510 may, for example, be patterned to have function of receiving or transmitting a signal. The covering layer 520 is used to protect the pattern layer 510 and reduce signal loss.

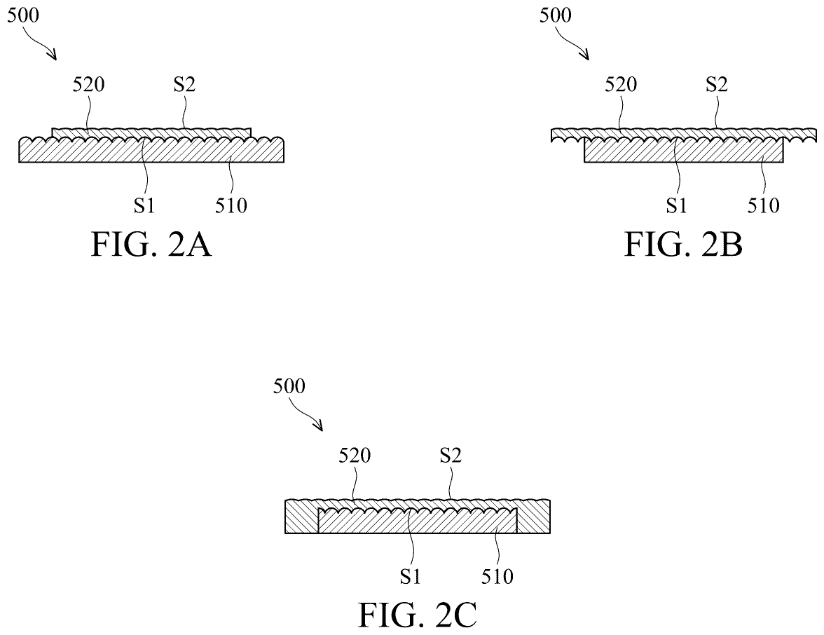

In some embodiments, the top surface of covering layer 520 is in direct contact with air. In some embodiments, the width of the covering layer 520 may be less than, equal to, or greater than the pattern layer 510 (please refer to FIGS. 2A to 2C for details). In some embodiments, the covering layer 520 partially overlaps the pattern layer 510. It should be noted that the “width” here refers to the length in the first direction X on the cross-section between the first direction X and the second direction Z.

In some embodiments, the roughness of the first surface S1 between the pattern layer 510 and the covering layer 520 is greater than the roughness of the second surface S2 of the covering layer 520 exposed to the air (refer to FIGS. 2A to 2C). That is, the second surface S2 of the covering layer 520 is a relatively smooth surface, and the first surface S1 is a relatively rough surface. Thereby, the covering layer 520 may protect the pattern layer 510 and prevent it from being oxidized.

It should be noted that the “surface” here may be listed as the interface between layers, the surface in contact with air, and the like. In addition, when the “surface” is the interface between the first layer and the second layer, the “surface” may be the surface of the first layer or it may also be the surface of the second layer.

In addition, the measurement of the size and roughness described in this case may include the use of a scanning electron microscope (SEM), a transmission electron microscope (TEM) and the like, and observation of the surface undulations at the same magnification. Also, compare the fluctuation conditions by taking a unit length (for example, 10 μm). Here, “appropriate magnification” means that at least 10 undulating peaks may be seen on at least one surface under the field of view at this magnification. In one embodiment, the roughness value is obtained through the ten point height of irregularities (Rz) method, which is defined as the average of the five highest peaks and the five deepest valleys within a measurement length.

In some embodiments, the pattern layer 510 may include conductive materials similar to those mentioned above, which will not be described again here. The covering layer 520 may include a metal or metal alloy, such as copper, titanium, molybdenum, nickel, nickel gold, nickel palladium gold, or the like. In the embodiment of the present invention, the pattern layer 510 may be electroplated copper, which has a relatively rough surface, thereby increasing its adhesion to the surrounding dielectric layer. By using the above-mentioned materials (which are relatively dense), the covering layer 520 may further make the surface smoother.

Next, as shown in FIG. 1, the electronic device 10 includes a second connector 600 disposed on the protective layer 100 on the opposite side from the first connector 400. Similar to the first connector 400, the second connector 600 may also realize the electrical connection relationship required by each component. For example, it may be a redistribution layer (RDL) structure and include a plurality of dielectric layers and a plurality of conductive layers. For example, in the embodiment of the present invention, the second connector 600 is a redistribution layer structure and is electrically connected to the chip 200 through the via hole TV, the vias V and the pads P1.

In some embodiments, the second connector 600 is similar to the first connector 400 and may include a conductive layer 600M1, a connecting line segment 600C, a conductive layer 600M2, and a dielectric layer 600D surrounding these. The conductive layer 600M1 and the conductive layer 600M2 may extend along the first direction X, and the connecting line segment 600C may extend along the second direction Z and electrically connect the conductive layer 600M1 and the conductive layer 600M2. The conductive layer 600M2 may serve as a pad to be electrically connected to the joint element B described later. Similarly, those with ordinary knowledge in the technical field of the present invention may arbitrarily arrange other numbers of conductive layers under the conductive layer 600M1, between the conductive layer 600M1 and the conductive layer 600M2, or on the conductive layer 600M2 according to actual needs.

In addition, the materials of the conductive layer 600M1, the conductive layer 600M2, the connecting line segment 600C and the dielectric layer 600D may be similar to the conductive layer 400M1, the conductive layer 400M2, the connecting line segment 400C and the dielectric layer 400D respectively, which will not be described again here.

Next, as shown in FIG. 1, the electronic device 10 includes at least one joint element B disposed on the second connector 600. In some embodiments, the joint element B is on the opposite side of the chip 200 from the antenna unit 500. In some embodiments, the joint element B may be electrically connected to the conductive layer 600M2 of the second connector 600. In some embodiments, the joint element B may include a binary, ternary or multi-element alloy composed of copper, silver, gold, nickel, titanium, tin, indium, germanium, platinum, palladium and other metals, but is not limited thereto. In some embodiments, the joint element B may be a solder ball, a bump, a pad, a copper pillar, or other suitable joint elements. The joint element B may include, for example, copper, tin, nickel, gold, lead, silver, gallium, other suitable conductive materials or combinations of the above materials, but not limited to the above. The second connector 600 and the substrate 700 described later are electrically connected through the joint element B (referring to FIG. 4).

As above, embodiments of the present invention may achieve the effects of reducing size and cost by integrating the chip 200 and the antenna unit 500 in the second direction Z. In addition, in the embodiment of the present invention, the covering layer 520 in the antenna unit 500 may protect the underlying pattern layer 510 and reduce signal loss. Furthermore, since the roughness of the first surface of the covering layer 520 that contacts the air is greater than the roughness of the second surface that contacts the pattern layer 510, the pattern layer 510 may be prevented from being oxidized.

Next, referring to FIGS. 2A-2C, FIGS. 2A-2C show cross-sectional schematic diagrams of different configurations of the antenna unit 500 of the electronic device 10.

First, as shown in FIG. 2A, the width of the pattern layer 510 is greater than the width of the covering layer 520. That is, in the first direction X, the length of the pattern layer 510 is greater than the length of the covering layer 520. In addition, the first surface S1 is the surface where the pattern layer 510 and the covering layer 520 are in contact. The second surface S2 is the surface of the covering layer 520 that contacts the air (or the surface away from the pattern layer 510). That is, the first surface S1 may belong to the pattern layer 510, or it may also belong to the covering layer 520, or it may belong to both the pattern layer 510 and the covering layer 520.

As shown in FIG. 2B, the width of the pattern layer 510 is less than the width of the covering layer 520. That is, in the first direction X, the length of the pattern layer 510 is less than the length of the covering layer 520.

As shown in FIG. 2C, the width of the pattern layer 510 is less than the width of the covering layer 520. Furthermore, the covering layer 520 covers the side surface of the pattern layer 510.

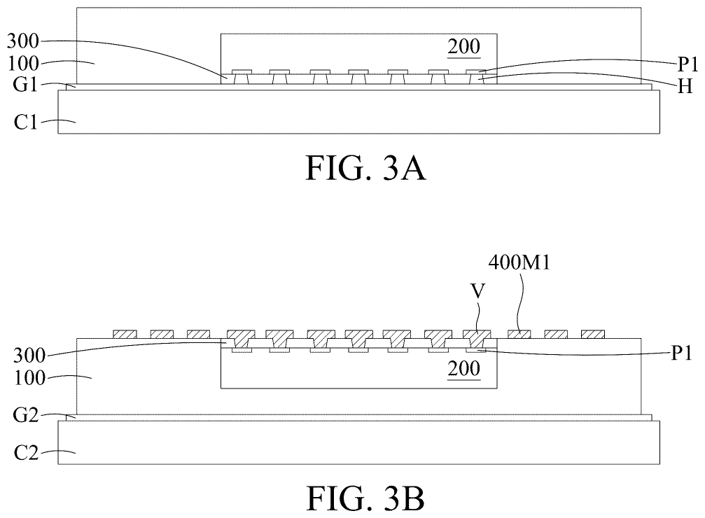

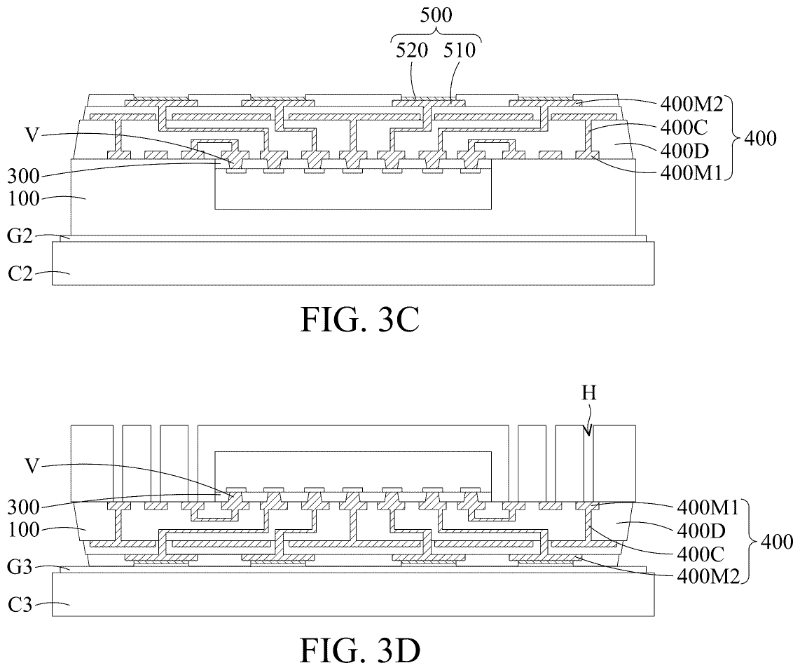

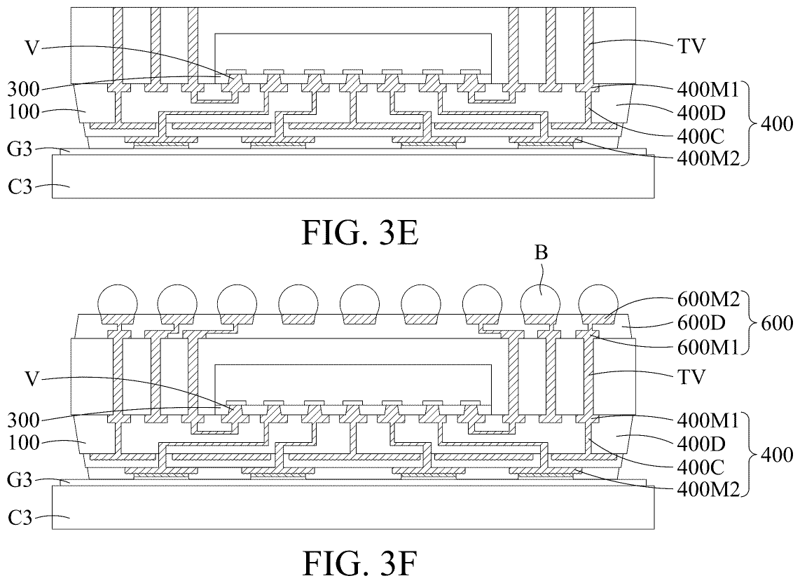

Next, please referring to FIGS. 3A-3F, FIGS. 3A-3F illustrate an example of a method of forming the electronic device 10.

As shown in FIG. 3A, a chip 200 is provided, and the pad P1 and the dielectric layer 300 are formed thereon. Next, an opening H is formed on the dielectric layer 300 corresponding to the pad P1.

The formation of the pad P1 may include a deposition process and a patterning process (including a photolithography process and an etching process), but is not limited thereto. The deposition process may include deposition methods including chemical vapor deposition (CVD), physical vapor deposition (PVD), sputtering, resistance heating evaporation, electron beam evaporation, or any other suitable method. The etching process may include a dry etching process or a wet etching process, such as reactive ion etching (RIE), neutral beam etching (NBE), a suitable etching process or a combination of the above, but not limited thereto.

The formation of the dielectric layer 300 may include a deposition process, such as chemical vapor deposition (CVD), atomic layer deposition (ALD), lamination or spin coating, or other suitable processes., but not limited thereto. The chemical vapor deposition method may be, for example, low pressure chemical vapor deposition (LPCVD), low temperature chemical vapor deposition (LTCVD), or rapid thermal chemical vapor deposition (RTCVD), plasma enhanced chemical vapor deposition (PECVD), and the like, but are not limited thereto. The formation of the opening H may include the etching process similar to the above, which will not be described again.

As shown in FIG. 3A, a side of the chip 200 formed with the dielectric layer 300 and the opening H is adhered to the carrier C1 having the adhesive layer G1.

The carrier C1 may be a non-adhesive base material, such as glass, steel plate, silicon oxide (SiOx), silicon nitride (SiNx), silicon oxynitride (SiOxNy) or other suitable materials, but not limited thereto. The adhesive layer G1 may include polycrystalline carbonate, polycarbodiimide, epoxy resin, poly-vinyl acetal, acrylic resin, polyester, other suitable adhesive materials or a combination of the foregoing, but not limited thereto. In some embodiments, the adhesive layer G1 may have thermal release or optical release properties.

As shown in FIG. 3A, a protective layer 100 is formed on the carrier C1 and covers the chip 200. The formation of the protective layer 100 may include transfer molding and compression molding. For example, the granule molding compound (GMC) may be evenly spread and then compressed and molded by heating and pressure.

As shown in FIG. 3B, the chip 200 surrounded by the protective layer 100 is inverted and adhered to the carrier C2 with the adhesive layer G2. Furthermore, a vias V is formed in the opening H, and a conductive layer 400M1 is formed on the protective layer 100. The vias V and the conductive layer 400M1 may be formed simultaneously through a deposition process (such as electroplating), and then through a patterning process to form a predetermined pattern. According to some embodiments, a recess may be dug in the protective layer 100, and then the chip 200 is placed in the recess, and the conductive layer 400M1 is formed on the protective layer 100, so that the conductive layer is electrically connected to the chip, but is not limited thereto. According to some embodiments, the conductive layer 400M1 may be a dummy or alignment mark, but is not limited thereto.

As shown in FIG. 3C, a dielectric layer 400D, a connecting line segment 400C and a conductive layer 400M2, a pattern layer 510 and a covering layer 520 are formed on the protective layer 100, thereby completing the first connector 400 and the antenna unit 500. The formation of the first connector 400 may include multiple deposition processes and etching processes, which are similar to those described above and will not be described again here. The formation of the antenna unit 500 may include a deposition process and a patterning process, so that the pattern layer 510 and the covering layer 520 become the predetermined pattern. The relevant process is similar to the above and will not be described again here.

As shown in the FIG. 3D, the chip 200 and the first connector 400 surrounded by the protective layer 100 are inverted and adhered to the carrier C3 with the adhesive layer G3. Furthermore, a through hole H is formed in the protective layer 100. The through hole H may have different shapes, such as straight tube shaped, trapezoid shaped, or neck shaped. The formation of the through hole H may include laser drilling or mechanical drilling to penetrate the protective layer 100 from the surface of the protective layer 100 that is exposed to the air until the conductive layer 400M1 of the first connector 400 is exposed.

As shown in FIG. 3E, a via hole TV is formed in the through hole H. The formation of the via hole TV may include electroplating, deposition processes, and the like, such as deep hole electroplating.

As shown in FIG. 3F, a conductive layer 600M1, a dielectric layer 600D, a connecting line segment 600C, and a conductive layer 600M2 are formed on the via hole TV, thereby completing the second connector 600. The formation of the second connector 600 may include multiple deposition processes and etching processes, which are similar to those described above and will not be described again here.

As shown in FIG. 3F, after the joint element B is formed on the second connector 600 corresponding to the conductive layer 600M2, another carrier C3 with the adhesive layer G3 is removed, and electronic device 10 as shown in FIG. 1 is obtained. The formation of the joint element B may include reflow soldering, but is not limited thereto.

Next, please referring to FIG. 4, FIG. 4 shows a schematic cross-sectional view of an electronic device according to other embodiments of the present disclosure.

In detail, the electronic device 20 in FIG. 4 is similar to the electronic device 10 in FIG. 1. The difference is that the electronic device 20 further includes a substrate 700 disposed on the joint element B. That is, the joint element B is provided between the substrate 700 and the second connector 600. The joint element B and the substrate 700 are on one side of the protective layer 100, and the antenna unit 500 is on the other side of the protective layer 100. That is, the joint element B and the antenna unit 500 are on opposite sides of the protective layer 100.

In some embodiments, the substrate 700 may be a driving element, such as a printed circuit board (PCB) or a flexible printed circuit (FPC), chip on film (COF), integrated circuit (IC), or combinations thereof, or the like, but are not limited thereto. The substrate 700 described in this disclosure may include steel plate, glass, polyimide (PI), polyethylene terephthalate (PET), wafer, other suitable materials, or combinations of the above materials.

In addition, the electronic device 20 also includes a pad P2 disposed between the substrate 700 and the joint element B to electrically connect them. The formation and material of the pad P2 are similar to those mentioned above and will not be described again.

In addition, the electronic device 20 also includes a functional element F, which may be electrically connected to the conductive layer 400M1. The functional element F may be an integrated passive device (IPD), a thin film transistor (TFT), a sensor, or other suitable elements.

In addition, in the electronic device 20, the conductive layer 400M1 is used to replace the vias V to electrically connect the chip 200 to the antenna unit 500 and/or the joint element B. It should be noted that features of various embodiments may be mixed and matched as long as they do not violate the spirit of the invention or conflict with each other.

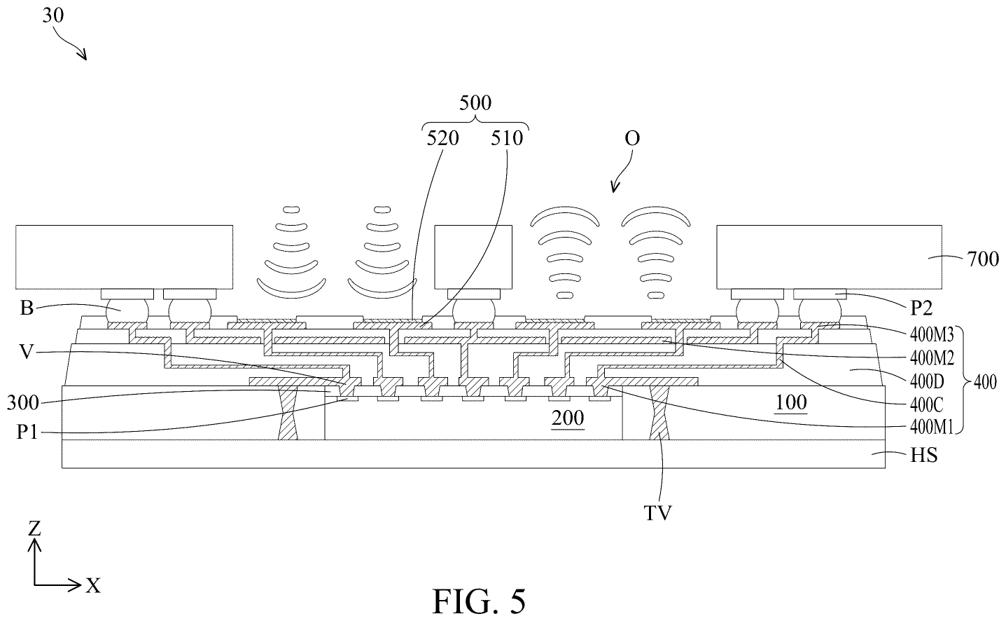

Next, please referring to FIG. 5, FIG. 5 shows a schematic cross-sectional view of an electronic device according to still other embodiments of the present disclosure.

In detail, the electronic device 30 in FIG. 5 is similar to the electronic device 20 in FIG. 2. The difference is that in the electronic device 30, the substrate 700 and the antenna unit 500 are disposed on the same side of the protective layer 100. Moreover, the electronic device 30 does not have the second connector 600. That is, the joint element B is provided between the substrate 700 and the first connector 400. As shown in the embodiment of FIG. 5, the substrate 700 has an opening O, which corresponds to the antenna unit 500. That is, in the first direction X, the antenna unit 500 and the substrate 700 do not overlap. In addition, in the embodiment of FIG. 5, in the opening O near the left side (direction −X side), the signal is emitted by the antenna unit 500, while in the opening O near the right side (direction +X side), the signal is received by the antenna unit 500.

In addition, the electronic device 30 further includes a heat sink HS disposed on one side of the protective layer 100 relative to the first connector 400. Moreover, the heat sink HS may be electrically connected to the conductive layer 400M1 through the via hole TV. This helps the electronic device dissipate heat. Here, different forms of via holes TV may be used to increase heat dissipation or improve electromagnetic interference (EMI). For example, the via holes TV may be straight tube shaped, trapezoid shaped, or neck shaped. In the embodiment of FIG. 5, the via hole TV is neck-shaped. In an embodiment, in a cross-sectional view, the aspect ratio of the via hole TV is 2:1-20:1.

It should be noted that the features of various embodiments may be mixed and matched as long as they do not violate the spirit of the invention or conflict. The method of forming the electronic device 30 will be briefly described

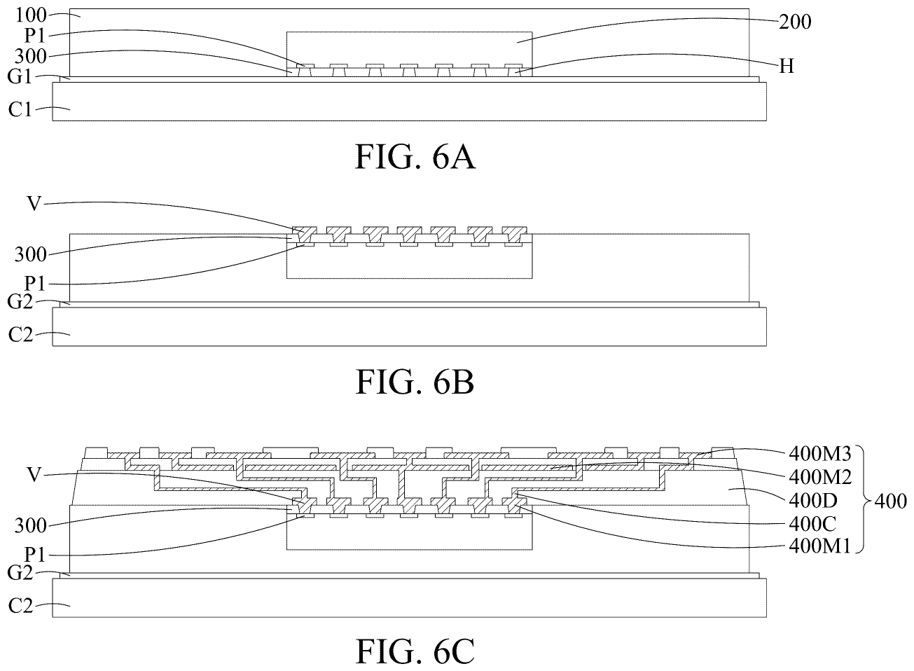

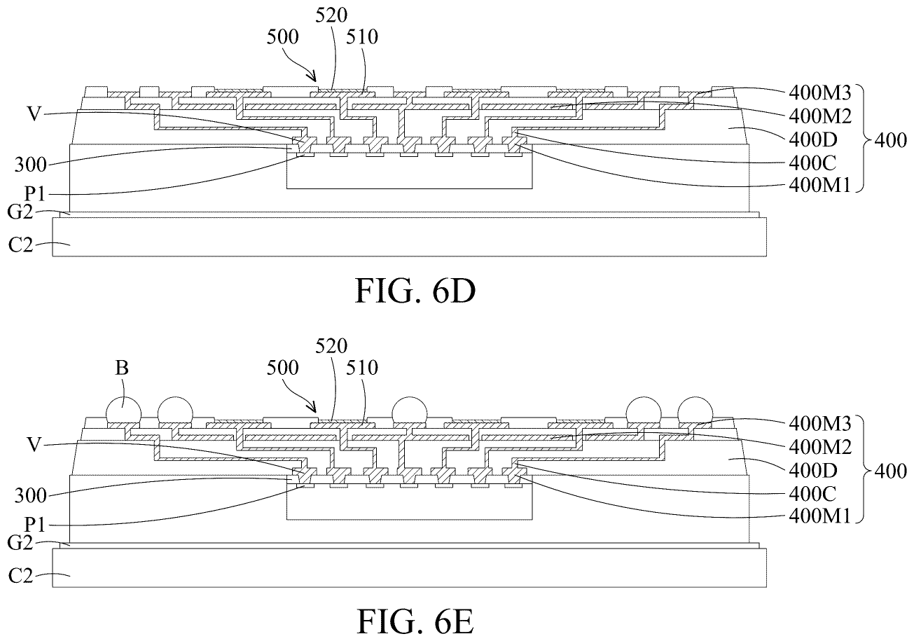

below, as shown in FIGS. 6A-6E. FIGS. 6A-6E illustrate an example of a method of forming the electronic device 30. FIGS. 6A-6E are similar to FIGS. 3A-3F, for simplicity, and only the differences are briefly described below.

FIGS. 6A-6B are the same as FIGS. 3A-3B, and will not be described again. As shown in FIGS. 6C, a first connector 400 is formed. It should be noted that at this time, a position for forming the joint element B must also be reserved on the first connector 400, so an area larger than that in FIG. 3C may be required. As shown in FIGS. 6D-6E, the antenna unit 500 is formed on the first connector 400 at a predetermined position. Furthermore, the joint element B is formed where the antenna unit 500 is not formed.

By disposing the antenna unit 500 and the joint element B on the same side of the protective layer 100, the steps of forming the second connector (without the second connector 600) may be reduced, and the process complexity may be further simplified, thereby reducing the manufacturing cost.

In summary, by including the covering layer, the antenna unit of the embodiment of the present invention may protect the pattern layer with signal receiving or transmitting functions and reduce signal loss. Furthermore, since the surface roughness between the covering layer and the pattern layer is greater than the roughness of the surface of the covering layer that contacts the air, it may resist oxidation and reduce signal loss while ensuring the adhesion of the pattern layer. In addition, embodiments of the present invention integrate the device by integrating the antenna unit and the chip in the second direction, thereby achieving the effect of reducing size and cost.

While the embodiments and the advantages of the present disclosure have been described above, it should be understood that those skilled in the art may make various changes, substitutions, and alterations to the present disclosure without departing from the spirit and scope of the present disclosure. It should be noted that different embodiments may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. An electronic device, comprising:
a protective layer;
a chip disposed on the protective layer;
a first connector electrically connected to the chip; and
an antenna unit disposed on the first connector and electrically connected to the chip,
wherein the antenna unit comprises a pattern layer and a covering layer disposed on the pattern layer,
wherein the pattern layer includes a first surface and the covering layer includes a second surface,
wherein a roughness of the first surface is greater than a roughness of the second surface.

2. The electronic device as claimed in claim 1, wherein the first surface contacts the covering layer.

3. The electronic device as claimed in claim 1, wherein the second surface is away from the pattern layer.

4. The electronic device as claimed in claim 1, wherein the second surface contacts the air.

5. The electronic device as claimed in claim 1, wherein the first connector comprises at least one conductive layer, wherein the conductive layer overlaps the chip in a direction, and wherein the at least one conductive layer is electrically connected to a ground terminal.

6. The electronic device as claimed in claim 1, wherein in a cross-sectional view, a width of the covering layer is less than a width of the pattern layer.

7. The electronic device as claimed in claim 1, wherein in a cross-sectional view, a width of the covering layer is greater than or equal to a width of the pattern layer.

8. The electronic device as claimed in claim 1, wherein the covering layer covers a side surface of the pattern layer.

9. The electronic device as claimed in claim 1, wherein the pattern layer comprises electroplated copper.

10. The electronic device as claimed in claim 1, wherein in a direction, the covering layer partially overlaps the pattern layer.

11. The electronic device as claimed in claim 1, wherein the first connector comprises a redistribution layer structure, which comprises a plurality of dielectric layers and a plurality of conductive layers.

12. The electronic device as claimed in claim 1, wherein the protective layer comprises an epoxy molding compound (EMC).

13. The electronic device as claimed in claim 1, further comprising:
a second connector disposed on the protective layer;
at least one joint element disposed on the second connector and disposed on an opposite side of the chip from the antenna unit; and
a substrate disposed on the at least one joint element, wherein the at least one joint element is disposed between the substrate and the second connector.

14. The electronic device as claimed in claim 13, wherein the at least one joint element comprises a solder ball, a bump, a pad, or a copper pillar.

15. The electronic device as claimed in claim 1, further comprising:
at least one joint element disposed on the first connector and disposed on a same side of the chip as the antenna unit; and
a substrate disposed on the at least one joint element, wherein the at least one joint element is disposed between the substrate and the first connector, wherein the substrate has at least one opening exposing the antenna unit.

16. The electronic device as claimed in claim 15, further comprising a heat sink disposed on a side of the protective layer that is opposite to the first connector.

17. The electronic device as claimed in claim 1, wherein the protective layer further comprises at least one via hole penetrating from a surface of the protective layer to another surface.

18. The electronic device as claimed in claim 17, wherein the at least one via hole is straight tube shaped, trapezoid shaped, or neck shaped.

19. The electronic device as claimed in claim 17, wherein an aspect ratio of the at least one via hole is 2:1-20:1.

20. The electronic device as claimed in claim 1, further comprising a plurality of pads and a plurality of vias electrically connecting the chip to the first connector.
